(19) United States
(12) Patent Application Publication
(10) Pub. No.: US 2025/0248026 A1
(43) Pub. Date: Jul. 31, 2025

(54) INTEGRATED CIRCUIT MEMORY DEVICES WITH HIGHLY INTEGRATED MEMORY CELL LAYOUTS THEREIN

(71) Applicant: Samsung Electronics Co., Ltd., Suwon-si (KR)

(72) Inventors: Jihee Jun, Suwon-si (KR); Changsik Kim, Suwon-si (KR); Youngkwan Park, Suwon-si (KR)

(21) Appl. No.: 18/751,690

(22) Filed: Jun. 24, 2024

(30) Foreign Application Priority Data
Jan. 25, 2024 (KR) 10-2024-0011772

(51) Int. Cl. H10B 12/00

(52) U.S. Cl. CPC H10B 12/315; H10B 12/05

(57) ABSTRACT

An integrated circuit memory device includes a bit line, which extends lengthwise in a first direction across an underlying substrate and has a trench therein with first and second opposing sidewalls. First and second spaced-apart word lines are provided, which extend lengthwise in parallel in a second direction across the underlying substrate, which is perpendicular to the first direction; the first word line has a first portion extending opposite the first sidewall of the trench and a second portion extending outside the trench, and the second word line has a first portion extending opposite the second sidewall of the trench and a second portion extending outside the trench. A semiconductor channel pattern is provided, which extends between the first portion of the first word line and the first sidewall of the trench, along a bottom of the trench.

### REFERENCE TO PRIORITY APPLICATION

This application claims priority under 35 USC § 112 to Korean Patent Application No. 10-2024-0011772, filed Jan. 25, 2024, the disclosure of which is hereby incorporated herein by reference.

### BACKGROUND

The present disclosure relates to integrated circuit devices and, more particularly, to integrated circuit memory devices and methods of fabricating same.

It is required to increase a degree of integration of integrated circuit memory devices in order to meet the excellent performance and low price required by consumers. In the case of semiconductor-type integrated circuit memory devices, because the degree of integration is an important factor in determining the price of a product, an increased degree of integration is typically required.

In the case of two-dimensional (2D) or planar semiconductor memory devices, because the degree of integration is mainly determined by an area occupied by a unit memory cell, it is greatly affected by a level of fine pattern formation technology. However, because ultra-high-priced equipment is required to refine patterns, the degree of integration of 2D semiconductor memory devices is increasing but still practically limited. Accordingly, semiconductor memory devices including vertical channel transistors whose channels extend in a vertical direction have been proposed.

### SUMMARY OF THE INVENTION

The present disclosure provides an integrated circuit device, including a semiconductor device, which is capable of reducing a contact resistance and improving an on-current Iₒₙ due to a wide contact area between a bit line and a channel pattern, and not only increasing Vₒ (output voltage) due to a wide contact area between the channel pattern and a contact pattern, but also preventing Vₜₕ (threshold voltage) from decreasing by first passivating the contact pattern before sufficiently passivating the channel pattern upon passivation of subsequent oxygen O₂.

According to an embodiment, a semiconductor device includes a substrate, a bit line located on the substrate and extending in a first direction, a word line located above the bit line and extending in a second direction different from the first direction, a channel pattern spaced apart from the word line in the first direction and including an oxide semiconductor material, and a gate insulating pattern located between the channel pattern and the word line. In some embodiments, the bit line includes a recess having an opening, the channel pattern includes a first portion located in the recess and a second portion located above the bit line, and a width of the recess in the first direction is greater than a width of the opening in the first direction.

According to another embodiment, a semiconductor device includes: a substrate, a bit line located on the substrate and extending in a first direction, a word line located above the bit line and extending in a second direction different from the first direction, a channel pattern spaced apart from the word line in the first direction and including an oxide semiconductor material, and a gate insulating pattern extending between the channel pattern and the word line. In some embodiments, the channel pattern includes a first portion inserted into the bit line and a second portion located above the bit line, and a thickness of the first portion of the channel pattern in the first direction is greater than a thickness of the second portion of the channel pattern in the first direction.

According to another embodiment, a semiconductor device includes: a substrate, a bit line located on the substrate and extending in a first direction, a word line located above the bit line and extending in a second direction different from the first direction, a channel pattern spaced apart from the word line in the first direction and including an oxide semiconductor material, and a gate insulating pattern located between the channel pattern and the word line. In some embodiments, the bit line has a recess therein, which opens upward, and the channel pattern includes a first portion located in the recess and a second portion located above the bit line; the first portion of the channel pattern may have a surface in contact with the bit line in the first direction in a concave shape toward the bit line.

According to an embodiment, the semiconductor device may reduce a contact resistance and improve an on-current (Iₒₙ) due to a wide contact area between a bit line and a channel pattern and not only increase Vₒ due to a wide contact area between the channel pattern and a contact pattern, but also prevent Vₜₕ from decreasing by first passivating the contact pattern before sufficiently passivating the channel pattern upon passivation of subsequent oxygen O₂.

According to a further embodiment, a semiconductor device includes a bit line, which extends in a first direction across an underlying substrate and has an opening therein at a first surface thereof and a recess within the opening; the recess has a greater lateral width as measured in the first direction relative to a width of the opening as measured in the first direction. A channel pattern is provided, which extends through the opening and at least partially fills the recess; the channel pattern extends in a second direction orthogonal to the first direction. A first word line is provided, which extends through the opening and into the recess, and extending lengthwise in the second direction. A gate insulating pattern is provided, which extends between the channel pattern and the first word line. In some of these embodiments, the recess includes opposing sidewalls that are concave shaped when viewed from a cross-sectional perspective, the channel pattern contacts the opposing concave shaped sidewalls of the recess, and the channel pattern forms a non-rectifying junction with the bit line along the opposing concave shaped sidewalls of the recess.

In another embodiment of the invention, an integrated circuit memory device is provided, which includes a bit line extending lengthwise in a first direction across an underlying substrate; the bit line has a trench therein with first and second opposing sidewalls. First and second spaced-apart word lines are provided, which extend lengthwise in parallel in a second direction across the underlying substrate, which is perpendicular to the first direction; the first word line has a first portion extending opposite the first sidewall of the trench and a second portion extending outside the trench, and the second word line has a first portion extending opposite the second sidewall of the trench and a second portion extending outside the trench. A channel pattern is provided, which extends between the first portion of the first word line and the first sidewall of the trench, along a bottom of the trench, and between the first portion of the second word line and the second sidewall of the trench. In some embodiments, each of the first and second opposing sidewalls is concave-shaped or convex-shaped when viewed from a cross-sectional perspective.

### BRIEF DESCRIPTION OF THE DRAWINGS

FIG. 1 is a layout diagram for explaining a semiconductor device according to an embodiment.

FIG. 2 is a cross-sectional view of the semiconductor device of FIG. 1 taken along lines A-A′ and B-B′.

FIG. 3 is an enlarged cross-sectional view of P1 of FIG. 2.

FIG. 4 is a diagram for explaining a semiconductor device according to some embodiments and is a cross-sectional view corresponding to FIG. 3.

FIG. 5 is a diagram for explaining a semiconductor device according to some embodiments and is a cross-sectional view corresponding to FIG. 3.

FIG. 6 is a diagram for explaining a semiconductor device according to some embodiments and is a cross-sectional view corresponding to FIG. 3.

FIGS. 7 to 21 are cross-sectional views for explaining a method of manufacturing a semiconductor memory device according to an embodiment.

FIGS. 22 to 24 are diagrams for explaining a method of manufacturing a semiconductor memory device according to some embodiments, and are cross-sectional views corresponding to FIGS. 9 and 10.

### DETAILED DESCRIPTION OF EMBODIMENTS

Hereinafter, with reference to the accompanying drawings, various embodiments of the present disclosure will be described in detail so that those skilled in the art may easily carry out the present disclosure. The present disclosure may be embodied in many different forms and is not limited to the embodiments set forth herein. In order to clearly explain the present disclosure in the drawings, parts irrelevant to the description are omitted, and the same reference numerals are used for the same or similar elements throughout the specification. In addition, since the size and thickness of each component shown in the drawings are arbitrarily shown for convenience of description, the present disclosure is not necessarily limited to those shown. In the drawings, the thickness of layers and regions are exaggerated for clarity. In addition, in the drawings, for convenience of explanation, thicknesses of some layers and areas are exaggerated. It will also be understood that when an element such as a layer, film, region, or substrate is referred to as being “on” another element, it may be directly on the other element or intervening elements may also be present. In contrast, when an element is referred to as being “directly on” another element, there are no intervening elements present. In addition, being “above” or “on” a reference part means being above or below the reference part, and does not necessarily mean being “above” or “on” in the opposite direction of gravity.

Throughout the specification, unless explicitly described to the contrary, the word “comprise” will be understood to imply the inclusion of stated elements but not the exclusion of any other elements. In addition, two directions parallel to an upper surface of a substrate and intersecting each other are defined as a first direction (Y direction) and a second direction (X direction), respectively, and a direction perpendicular to the upper surface of the substrate is explained as a third direction (Z direction). For example, the first direction (Y direction) and the second direction (X direction) may be perpendicular to each other.

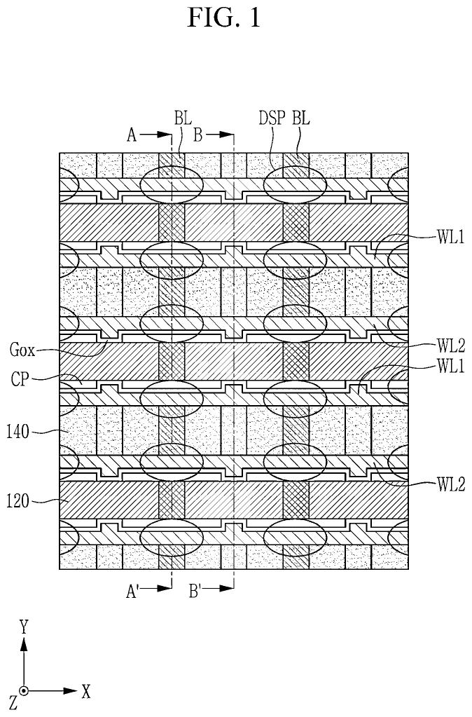

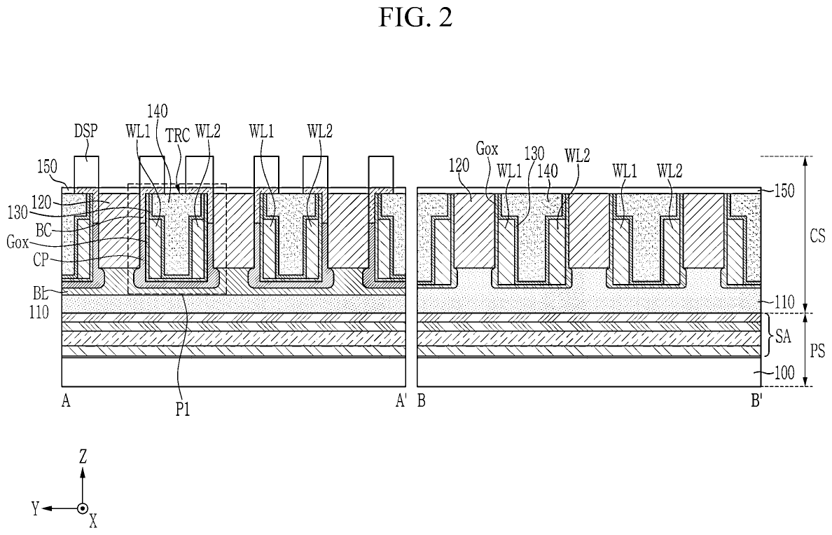

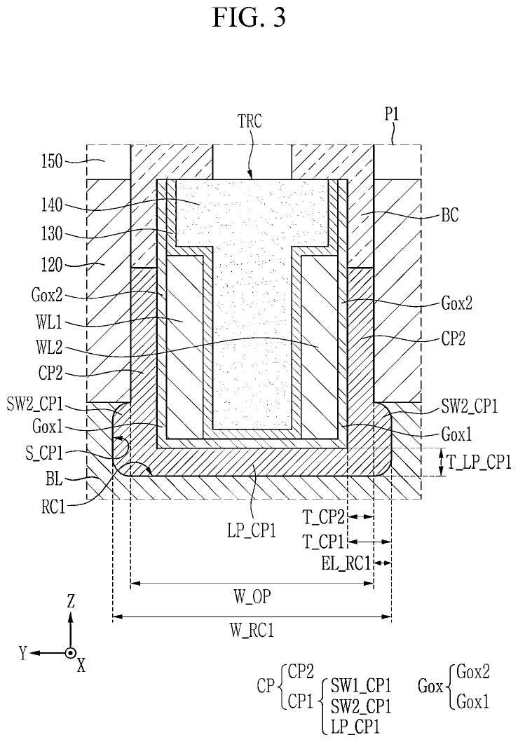

Hereinafter, a semiconductor device according to an embodiment will be described in detail with reference to FIGS. 1 to 3, where FIG. 1 is a layout diagram for explaining a semiconductor device according to an embodiment, FIG. 2 is a cross-sectional view of the semiconductor device of FIG. 1 taken along lines A-A′ and B-B′, and FIG. 3 is an enlarged cross-sectional view of P1 of FIG. 2.

Referring to FIGS. 1 to 3, a semiconductor device 100 according to an embodiment may include a peripheral circuit structure PS and a cell array structure CS located on the peripheral circuit structure PS. The peripheral circuit structure PS may include a substrate 100, a core integrated on an upper surface of the substrate 100, and peripheral circuits SA. The substrate 100 may have a structure in which a base substrate and an epi layer are stacked, but is not limited thereto. For example, the substrate 100 may be a silicon substrate, a gallium arsenide substrate, a silicon germanium substrate, or a semiconductor on insulator (SOI) substrate. Hereinafter, it is described that the substrate 100 is a silicon substrate. The core and the peripheral circuits SA may include NMOS and PMOS transistors integrated on the substrate 100. The core and the peripheral circuits SA may be electrically connected to a bit line BL through peripheral circuit wirings and peripheral circuit contact plugs. That is, sense amplifiers may be electrically connected to the bit line BL, and each sense amplifier may amplify and output a difference in voltage levels detected by a pair of bit lines BL.

The cell array structure CS may include memory cells including a vertical channel transistor (VCT). The VCT may refer to a structure in which a channel length extends in a direction (e.g., a third direction Z) perpendicular to the upper surface of the substrate 100. In an embodiment, the cell array structure CS may include a lower insulating layer 110, the bit line BL, a first insulating pattern 120, channel patterns CP, word lines WL1 and WL2, a gate insulating pattern Gox, a second insulating pattern 130, a third insulating pattern 140, a contact pattern LP, an interlayer insulating layer 150, and a data storage pattern DSP.

The lower insulating layer 110 may cover the core and the peripheral circuits SA, the peripheral circuit wirings, and the peripheral circuit contact plugs on the substrate 100. The lower insulating layer 110 may include insulating films stacked in multiple layers. For example, the lower insulating layer 110 may include a silicon oxide film, a silicon nitride film, a silicon nitric oxide film, a low-k dielectric film, or a combination thereof.

The bit line BL may be located on the substrate 100. For example, the lower insulating layer 110 may be located on the substrate 100, and the bit line BL may be located on the lower insulating layer 110. The bit lines BL extend in a first direction (Y direction) and may be arranged to be spaced apart in a second direction (X direction). The lower insulating layer 110 may be located to fill a space between the bit lines BL. For example, an upper surface of the lower insulating layer 110 and an upper surface of the bit line BL may be located at substantially the same level.

The bit line BL may include doped polysilicon, metal, conductive metal nitride, conductive metal silicide, conductive metal oxide, or a combination thereof. For example, the bit line BL may be made of Al, Cu, Ti, Ta, Ru, W, Mo, Pt, Ni, Co, TiN, TaN, WN, NbN, TiAlN, TiSi, TiSiN, TaSi, TaSiN, RuTiN, NiSi, CoSi, IrOₓ, RuOₓ, or a combination thereof, but is not limited thereto. The bit line BL may include a single layer or multiple layers of the above-described materials. And, in some embodiments, the bit line BL may include a two-dimensional (2D) semiconductor material, for example, graphene, carbon nanotube, or a combination thereof.

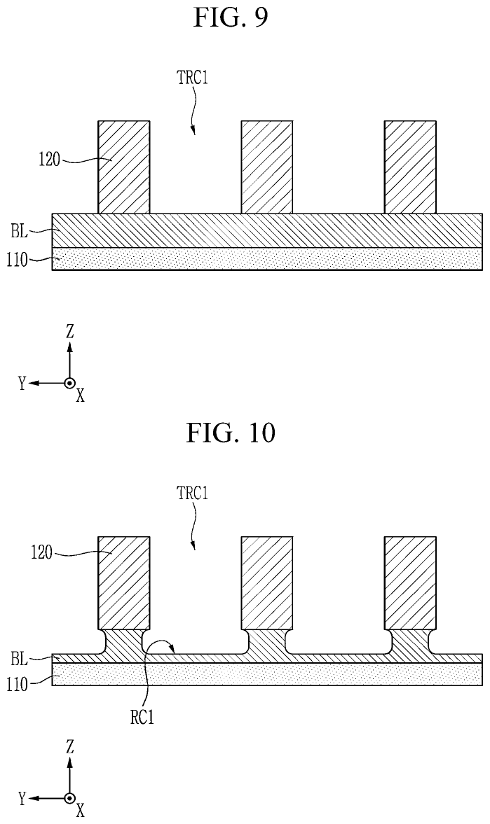

The bit line BL has an opening therein with a first recess RC1 that opens in the third direction (Z direction). As will be described below with reference to FIGS. 9 and 10, after forming the first insulating patterns 120 defining first trenches TRC1, the first recess RC1 may be formed by etching the bit line BL. At this time, the first recess RC1 may have an enlarged structure by laterally over-etching the bit line BL. In other words, a width W_RC of the first recess RC1 in the first direction (Y direction) in the bit line BL may be greater than a distance between the first insulating patterns 120 in the first direction (Y direction), that is, a width of the first trench TRC1 in the first direction (Y direction). Here, the width W_RC of the first recess RC1 in the first direction (Y direction) may be the maximum width among widths of the first recess RC1 in the first direction (Y direction).

Accordingly, the width W_RC of the first recess RC1 in the first direction (Y direction) may be greater than a width W_OP of an opening of the first recess RC1 in the first direction (Y direction). Here, the width W_OP of the opening of the first recess RC1 in the first direction (Y direction) may be the width of the first recess RC1 in the first direction (Y direction) in an uppermost end of the first recess RC1 in the third direction (Z direction). In addition, the width W_RC of the first recess RC1 in the first direction (Y direction) may be greater than the distance between the first insulating patterns 120 in the first direction (Y direction), which will be described below. In addition, the width W_RC of the first recess RC1 in the first direction (Y direction) may be greater than the width of the first trench TRC1 (in FIG. 10) in the first direction (Y direction), which will be described below.

In addition, the width W_RC of the first recess RC1 in the first direction (Y direction) in the bit line BL may have the maximum value at any point inside the bit line BL, and the width W_RC of the first recess RC1 in the first direction (Y direction) in the bit line BL may have the minimum value in the uppermost end or the lowermost end of the first recess RC1 in the third direction (Z direction). For example, the width W_RC of the first recess RC1 in the first direction (Y direction) in the bit line BL may have a shape gradually increasing toward the inside of the bit line BL, that is, downward in the third direction (Z direction), reaching the maximum value, and then gradually decreasing.

Accordingly, the first recess RC1 may have an extension portion EL_RC1 protruding toward the bit line BL in the first direction (Y direction). Here, the extension portion EL_RC1 of the first recess RC1 refers to a portion in which the width W_RC of the first recess RC1 in the first direction (Y direction) is greater than the distance between the first insulating patterns 120 in the first direction (Y direction). At this time, the extension portion EL_RC1 of the first recess RC1 may have a surface in contact with the bit line BL in the first direction (Y direction) in a convex shape toward the bit line BL, that is, the extension portion EL_RC1 of the first recess RC1 may have a shape that protrudes toward the bit line BL.

The first insulating pattern 120 is located above the bit line BL and may extend in the second direction (X direction). The first insulating pattern 120 may be arranged to intersect the bit line BL. The first insulating patterns 120 may be spaced apart in the first direction (Y direction). As the first insulating patterns 120 are spaced apart in the first direction (Y direction), channel trenches TRC may be formed between the first insulating patterns 120. The channel trenches TRC may extend in the second direction (X direction) like the first insulating patterns 120 and may be arranged to be spaced apart in the first direction (Y direction).

The first insulating pattern 120 may include, for example, silicon oxide, silicon nitric oxide, silicon nitride, a low-k material having a smaller dielectric constant than silicon oxide, or a combination thereof, but is not limited thereto.

The low-k material may include, for example, FOX (Flowable Oxide), TOSZ (Torene SilaZene), USG (Undoped Silicate Glass), BSG (Borosilicate Glass), PSG (PhosphoSilicate Glass), BPSG (BoroPhosphoSilicate Glass), PETEOS (Plasma Enhanced Tetra Ethyl Ortho Silicate), FSG (Fluoride Silicate Glass), CDO (Carbon Doped silicon Oxide), Xerogel, Aerogel, Amorphous Fluorinated Carbon, OSG (Organo Silicate Glass), Parylene, BCB (bis-benzocyclobutenes), SiLK, polyimide, porous polymeric material, or a combination thereof, but is not limited thereto.

The channel pattern CP includes a first portion CP1 inserted into the bit line BL and a second portion CP2 located above the bit line BL. In other words, the first portion CP1 of the channel pattern CP is located in the first recess RC1, and the second portion CP2 is located above the bit line BL. The first portion CP1 of the channel pattern CP may include a first sidewall portion SW1_CP1 and a second sidewall portion SW2_CP1 which are located within the first recess RC1 and are disposed adjacent to sidewalls of the first recess RC1 facing each other in the first direction (Y direction), and a lower end portion LP_CP1 disposed on a bottom surface of the first recess RC1 and connecting between the first sidewall portion SW1_CP1 and the second sidewall portion SW2_CP1.

The second portion CP2 of the channel pattern CP may be located adjacent to the sidewall of the first insulating pattern 120. The second portion CP2 of the channel pattern CP may be located within the channel trench TRC. In other words, the second portion CP2 of the channel pattern CP may be located above the bit line BL, and may be located on each of the first sidewall portion SW1_CP1 and the second sidewall portion SW2_CP1 of the first portion CP1 of the channel pattern CP. Accordingly, the channel pattern CP may have an overall “U” shape on a cross-section cut in the first direction (Y direction) and the third direction (Z direction).

The first portion CP1 of the channel pattern CP may fill the extension portion EL_RC1 of the first recess RC1. Accordingly, a thickness T_CP1 of the first sidewall portion SW1_CP1 or the second sidewall portion SW2_CP1 of the first portion CP1 of the channel pattern CP in the first direction (Y direction) may be greater than a thickness T_CP2 of the second portion CP2 of the channel pattern CP in the first direction (Y direction). Here, the thickness T_CP1 of the first sidewall portion SW1_CP1 or the second sidewall portion SW2_CP1 of the first portion CP1 of the channel pattern CP in the first direction (Y direction) may be the maximum thickness of the first sidewall portion SW1_CP1 or the second sidewall portion SW2_CP1 of the first portion CP1 of the channel pattern CP in the first direction (Y direction), and the thickness T_CP2 of the second portion CP2 of the channel pattern CP in the first direction (Y direction) may be the maximum thickness of the second portion CP2 of the channel pattern CP in the first direction (Y direction).

For example, when the thickness T_CP2 of the second portion CP2 of the channel pattern CP in the first direction (Y direction) is 1, the thickness T_CP1 of the first sidewall portion SW1_CP1 or the second sidewall portion SW2_CP1 of the first portion CP1 of the channel pattern CP in the first direction (Y direction) may be 1.1 or more, for example, 1.2 or more, 1.3 or more, 1.4 or more, 1.5 or more, or 2 or more, and may be 2 or less, 1.5 or less, 1.4 or less, 1.3 or less, or 1.2 or less.

In addition, the thickness T_CP1 of the first sidewall portion SW1_CP1 or the second sidewall portion SW2_CP1 of the first portion CP1 of the channel pattern CP in the first direction (Y direction) may be greater than a thickness T_LP_CP1 of the lower end portion LP_CP1 of the first portion CP1 of the channel pattern CP in the third direction (Z direction). Here, the thickness T_LP_CP1 of the lower end portion LP_CP1 of the first portion CP1 of the channel pattern CP in the third direction (Z direction) may be the maximum thickness of the lower end portion LP_CP1 of the first portion CP1 of the channel pattern CP in the third direction (Z direction).

For example, when the thickness T_LP_CP1 of the lower end portion LP_CP1 of the first portion CP1 of the channel pattern CP in the third direction (Z direction) is 1, the thickness T_CP1 of the first sidewall portion SW1_CP1 or the second sidewall portion SW2_CP1 of the first portion CP1 of the channel pattern CP in the first direction (Y direction) may be 1.1 or more, 1.2 or more, 1.3 or more, 1.4 or more, 1.5 or more, or 2 or more, and may be 2 or less, 1.5 or less, 1.4 or less, 1.3 or less, or 1.2 or less.

In addition, the thickness T_CP1 of the first sidewall portion SW1_CP1 or the second sidewall portion SW2_CP1 of the first portion CP1 of the channel pattern CP in the first direction (Y direction) may have the maximum value at any one point within the bit line BL, and the thickness T_CP1 of the first sidewall portion SW1_CP1 or the second sidewall portion SW2_CP1 of the first portion CP1 of the channel pattern CP in the first direction (Y direction) may have the minimum value in the uppermost end or the lowermost end of the first recess RC1 in the third direction (Z direction). For example, the thickness T_CP1 of the first sidewall portion SW1_CP1 or the second sidewall portion SW2_CP1 of the first portion CP1 of the channel pattern CP in the first direction (Y direction) may have a shape gradually increasing toward the inside of the bit line BL, that is, downward in the third direction (Z direction), reaching the maximum value, and then gradually decreasing.

Accordingly, the first portion CP1 of the channel pattern CP may have a surface S_CP1 in contact with the bit line BL in the first direction (Y direction) in a convex shape toward the bit line BL, that is, the first sidewall portion SW1_CP1 or the second sidewall portion SW2_CP1 of the first portion CP1 of the channel pattern CP may have a shape that protrudes toward the bit line BL. As described above, a contact area between the bit line BL and the channel pattern CP increases, and thus, a contact resistance of the semiconductor device may be reduced, and an on current Iₒₙ may be improved.

For example, the channel pattern CP may have an overall conformal shape. That is, the channel pattern CP may cover a bottom surface of the first recess RC1 of the bit line BL, a sidewall of the first recess RC1 of the bit line BL, and a sidewall of the first insulating pattern 120 to a certain thickness, and the thickness T_CP2 of the second portion CP2 of the channel pattern CP in the first direction (Y direction) and the thickness T_LP_CP1 of the lower end portion LP_CP1 of the first portion CP1 of the channel pattern CP in the third direction (Z direction) may be similar to each other.

However, as the first portion CP1 of the channel pattern CP fills the extension portion EL_RC1 of the first recess RC1, the thickness T_CP1 of the first sidewall portion SW1_CP1 or the second sidewall portion SW2_CP1 of the first portion CP1 of the channel pattern CP in the first direction (Y direction) may be greater than each of the thickness T_CP2 of the second portion CP2 of the channel pattern CP in the first direction (Y direction) and the thickness T_LP_CP1 of the lower end portion LP_CP1 of the first portion CP1 of the channel pattern CP in the third direction (Z direction).

Meanwhile, the upper surface of the second portion CP2 of the channel pattern CP adjacent to the sidewall of the first insulating pattern 120 may be located at a lower level than the upper surface of the first insulating pattern 120. The upper surface of the second portion CP2 of the channel pattern CP adjacent to the sidewall of the first insulating pattern 120 may contact a contact pattern BC, which will be described below.

The channel patterns CP may be arranged to be spaced apart in the second direction (X direction) within the channel trench TRC. In other words, the first sidewall portion SW1_CP1 of the first portion CP1 of the channel pattern CP and the second portion CP2 thereon may be located on one side surface of the channel trench TRC in the first direction (Y direction), and the second sidewall portion SW2_CP1 of the first portion CP1 of the channel pattern CP and the second portion CP2 on the second sidewall portion SW2_CP1 thereon may be located on the other side surface of the channel trench TRC in the first direction (Y direction). However, the first sidewall portion SW1_CP1 and the second sidewall portion SW2_CP1 of the first portion CP1 of the channel pattern CP may be connected to each other by the lower end portion LP_CP1 on the bottom surface of the first recess RC1. In addition, the second insulating pattern 130 and the third insulating pattern 140, which will be described below, may be located between the adjacent channel patterns CP in the first direction (Y direction).

The channel pattern CP may include a first source/drain region and a second source/drain region. For example, the first portion CP1 of the channel pattern CP may be connected to the bit line BL and function as the first source/drain region, a part of the second portion CP2 of the channel pattern CP may be connected to the contact pattern BC and function as the second source/drain region, and the remaining part of the second portion CP2 of the channel pattern CP between the first source/drain region and the second source/drain region may function as a channel region.

The channel pattern CP may include an oxide semiconductor material. The oxide semiconductor material may be an oxide of materials including In, Ga, Zn, Al, Sn, Hf, or a combination thereof, but is not limited thereto. The oxide semiconductor material may further include a material such as Si, Mg, Ta, La, Nd, Ce, Sc, Cr, Co, Nb, Mo, Ba, Gd, Ti, W, Pd, Ru, Ni, or Mn to the above composition. For example, the channel pattern CP may include indium gallium zinc oxide (IGZO), indium tin zinc oxide (ITZO), indium zinc oxide (IZO), zinc oxide (ZnO), zinc tin oxide (ZTO), and zinc oxynitride (ZnON), zirconium zinc tin oxide (ZZTO), tin oxide (SnO), hafnium indium zinc oxide (HIZO), gallium zinc tin oxide (GZTO), aluminum zinc tin oxide (AZTO), ytterbium gallium zinc oxide (YGZO), IGO (indium gallium oxide), or a combination thereof. However, the channel pattern CP is not limited thereto, and the oxide semiconductor material included in the channel pattern CP may be changed in various ways.

According to some embodiments, the first portion CP1 and the second portion CP2 of the channel pattern CP may include different oxide semiconductor materials. For example, the second portion CP2 of the channel pattern CP may include IGZO, and the first portion CP1 of the channel pattern CP may exclude indium oxide, zinc oxide, gallium oxide, or a combination thereof and further include other oxides. Alternatively, the oxide semiconductor material of the first portion CP1 of the channel pattern CP and the oxide semiconductor material of the second portion CP2 of the channel pattern CP may have the same composition but different composition ratios. For example, when the first portion CP1 of the channel pattern CP and the second portion CP2 of the channel pattern CP include IGZO, the composition ratio of indium, gallium, zinc, and oxygen of the first portion CP1 of the channel pattern CP may be different from the composition ratio of indium, gallium, zinc, and oxygen of the second portion CP2 of the channel pattern CP.

For example, the first portion CP1 of the channel pattern CP may include an oxide semiconductor material with a higher composition ratio of indium than a material of the second portion CP2 of the channel pattern CP. As the composition ratio of indium increases, a contact resistance may be improved (reduced). The second portion CP2 of the channel pattern CP may include an oxide semiconductor material with a higher composition ratio of gallium than a material of the first portion CP1. The higher the composition ratio of gallium, the more the reliability may be improved. Here, improving reliability may mean reducing a change in film quality that occurs as the semiconductor device operates.

The word lines WL1 and WL2 may extend in the second direction (X direction) across the bit line BL and may be arranged to be spaced apart in the first direction (Y direction). The word lines WL1 and WL2 may be spaced apart from the bit line BL in the third direction (Z direction). A pair of word lines WL1 and WL2 may be located between the channel patterns CP within the channel trench TRC. The pair of word lines WL1 and WL2 may be located between the second portions CP2 of the channel pattern CP covering both sidewalls of the channel trench TRC. Each of the word lines WL1 and WL2 may have one side and the other side facing each other in the first direction (Y direction), and the pair of word lines WL1 and WL2 located in the channel trench TRC may be arranged so that one sides thereof face each other.

The word lines WL1 and WL2 may be spaced apart from the channel pattern CP. The word lines WL1 and WL2 may be spaced apart from the channel pattern CP by the gate insulating pattern Gox, which will be described below. That is, the gate insulating pattern Gox is located between the word lines WL1 and WL2 and the channel pattern CP. The word lines WL1 and WL2 may include upper and lower surfaces facing each other in the third direction (Z direction). The lower surfaces of the word lines WL1 and WL2 may face the bit line BL with the gate insulating pattern Gox and the channel pattern CP interposed therebetween. The upper surfaces of the word lines WL1 and WL2 may face the contact pattern BC with the second insulating pattern 130 and the third insulating pattern 140, which will be described below, interposed therebetween.

It is shown that the upper surfaces of the word lines WL1 and WL2 are located at a higher level than the upper surface of the second portion CP2 of the adjacent channel pattern CP, but the upper surfaces of the word lines WL1 and WL2 are not limited thereto, and may be located at substantially the same or lower level. The word lines WL1 and WL2 may include, for example, doped polysilicon, metal, conductive metal nitride, conductive metal silicide, conductive metal oxide, or a combination thereof. The word lines WL1 and WL2 may include, for example, Al, Cu, Ti, Ta, Ru, W, Mo, Pt, Ni, Co, TiN, TaN, WN, NbN, TiAl, TiAlN, TiSi, TiSiN, TaSi, TaSiN, RuTiN, NiSi, CoSi, IrOₓ, RuOₓ, or combination thereof, but are not limited thereto. The word lines WL1 and WL2 may include a single layer or multiple layers of the materials described above. In some embodiments, the word lines WL1 and WL2 may include a 2D semiconductor material, for example, graphene, carbon nanotube, or a combination thereof.

The gate insulating pattern Gox may be located between the channel pattern CP and the word lines WL1 and WL2. The gate insulating pattern Gox may conformally cover the channel pattern CP. That is, the gate insulating pattern Gox may be located adjacent onto the second portions CP2 of the pair of channel patterns CP facing each other in the channel trench TRC, the first sidewall portion SW1_CP1 and the second sidewall portion SW2_CP1 of the first portion CP1 of the channel pattern CP, and the lower end portion LP_CP1 of the first portion CP1 of the channel pattern CP.

The gate insulating pattern Gox covering the sidewall of the second portion CP2 of the channel pattern CP may further extend in the third direction (Z direction). However, it is shown that the gate insulating pattern Gox extends to substantially the same level as the upper surface of the first insulating pattern 120, but is not limited thereto. For example, the uppermost surface of the gate insulating pattern Gox may be located at a lower level than the upper surface of the first insulating pattern 120. In addition, the uppermost surface of the gate insulating pattern Gox may be located at a level substantially the same as or higher than the upper surfaces of the word lines WL1 and WL2.

The gate insulating pattern Gox may overlap the first sidewall portion SW1_CP1 and the second sidewall portion SW2_CP1 of the first portion CP1 of the channel pattern CP in the first direction (Y direction), and the second portion CP2 of the channel pattern CP. A part of the gate insulating pattern Gox that does not overlap the second portion CP2 of the channel pattern CP may be in contact with the contact pattern BC which is described below, and located between the contact pattern BC and the second insulating pattern 130. The gate insulating pattern Gox may overlap the lower end portion LP_CP1 of the first portion CP1 of the channel pattern CP in the third direction (Z direction). At this time, one side of the gate insulating pattern Gox may be adjacent to the lower end portion LP_CP1 of the first portion CP1 of the channel pattern CP, and the other side of the gate insulating pattern Gox may be adjacent to lower surfaces of the word lines WL1 and WL2 and the lower surface of the second insulating pattern 130.

However, FIG. 3 shows that the gate insulating pattern Gox is seamlessly connected along the lower end portion LP_CP1 of the first portion CP1 of the channel pattern CP in the first direction (Y direction) to have an overall “U” shape, but is not limited thereto, and a center part of the gate insulating pattern Gox adjacent to the lower end portion LP_CP1 of the first portion CP1 of the channel pattern CP is disconnected so that the gate insulating pattern Gox has an overall “└ ┘” shape, and the second insulating pattern 130 may be located between the disconnected center parts of the gate insulating pattern Gox.

The gate insulating pattern Gox may include silicon oxide, silicon nitric oxide, a high-k material having a higher dielectric constant than silicon oxide, or a combination thereof. The high-k material may include metal oxide or metal silicon nitric oxide. The high-k material may include, for example, HfO₂, HfSiO, HfSiON, HfTaO, HfTiO, HfZrO, ZrO₂, Al₂O₃, or a combination thereof. However, the gate insulating pattern Gox is not limited thereto, and the material included in the gate insulating pattern Gox may be changed in various ways.

The second insulating pattern 130 and the third insulating pattern 140 may be located in the channel trench TRC. The second insulating pattern 130 and the third insulating pattern 140 may be located above the word lines WL1 and WL2 and the gate insulating pattern Gox. The second insulating pattern 130 may contact the word lines WL1 and WL2 and the gate insulating pattern Gox. The second insulating pattern 130 may conformally cover the word lines WL1 and WL2 and the gate insulating pattern Gox. The second insulating pattern 130 may cover the upper surfaces and sidewalls facing each other of the word lines WL1 and WL2 located in the channel trench TRC. The second insulating pattern 130 may cover a part of the gate insulating pattern Gox that is not covered by the word lines WL1 and WL2 within the channel trench TRC. The second insulating pattern 130 may cover the upper surface of the gate insulating pattern Gox located between the word lines WL1 and WL2. The second insulating pattern 130 may cover the sidewall of the gate insulating pattern Gox that protrudes in the third direction (Z direction) from the upper surfaces of the word lines WL1 and WL2.

The third insulating pattern 140 may be located on the second insulating pattern 130. The third insulating pattern 140 may be spaced apart from the word lines WL1 and WL2 and the gate insulating pattern Gox by the second insulating pattern 130. That is, the second insulating pattern 130 may be located between the word lines WL1 and WL2 and the third insulating pattern 140, and between the gate insulating pattern Gox and the third insulating pattern 140. The third insulating pattern 140 may fill the channel trench TRC remaining after the second channel pattern CP2, the gate insulating pattern Gox, the word lines WL1 and WL2, and the second insulating pattern 130 are formed.

The third insulating pattern 140 may include a vertical portion located between the word lines WL1 and WL2 and a horizontal portion located above the upper surfaces of the word lines WL1 and WL2. Accordingly, the third insulating pattern 140 may have a “T” shape on a cross-section cut in the first direction (Y direction) and the third direction (Z direction). The vertical portion of the third insulating pattern 140 may extend in the third direction (Z direction) from the horizontal portion of the third insulating pattern 140 toward the bit line BL. The horizontal portion of the third insulating pattern 140 may be closer to the bit line BL than the vertical portion of the third insulating pattern 140. A width (Y direction) of the horizontal portion of the third insulating pattern 140 may be greater than a width of the vertical portion of the third insulating pattern 140 on the cross-section cut in the first direction (Y direction) and the third direction (Z direction).

The second insulating pattern 130 and the third insulating pattern 140 may include, for example, silicon oxide, silicon nitric oxide, silicon nitride, a low-k material having a smaller dielectric constant than silicon oxide, or a combination thereof, but is not limited thereto. For example, the second insulating pattern 130 and the third insulating pattern 140 may include different materials. For example, the second insulating pattern 130 may include silicon nitride, and the third insulating pattern 140 may include silicon oxide. When the second insulating pattern 130 and the third insulating pattern 140 include different materials, the second insulating pattern 130 and the third insulating pattern 140 may be sequentially formed, but when the second insulating pattern 130 and the third insulating pattern 140 include the same material, the second insulating pattern 130 and the third insulating pattern 140 may be integrally formed.

The contact pattern BC may be arranged to overlap at least a part of the channel pattern CP in the third direction (Z direction). The contact patterns BC may be arranged to be spaced apart from each other in the first direction (Y direction) and the second direction (X direction). The contact patterns BC may be arranged in matrix form, but this is only an example and is not limited thereto. The contact patterns BC may be arranged in various shapes, such as a honeycomb shape. In addition, the contact pattern BC may have a circular, oval, rectangular, square, rhombus, or hexagonal shape on a plane, but the planar shape of the contact pattern BC is not limited thereto.

The contact pattern BC may be electrically connected to the channel pattern CP. The contact pattern BC may contact at least a part of the channel pattern CP. In some embodiments, the contact pattern BC may be located between the first insulating pattern 120 and the gate insulating pattern Gox. The contact pattern BC may include a first portion extending in the first direction (Y direction) and a second portion extending from the first portion in the third direction (Z direction). The first portion of the contact pattern BC may be located on the upper surface of the gate insulating pattern Gox, an upper surface of the second insulating pattern 130, and an upper surface of the third insulating pattern 140. It is shown that a lower surface of the first portion of the contact pattern BC is located at substantially the same level as each of the upper surface of the first insulating pattern 120 and the upper surface of the third insulating pattern 140, but is not limited thereto. For example, the lower surface of the first portion of the contact pattern BC may be located at a lower level than each of the upper surface of the first insulating pattern 120 and the upper surface of the third insulating pattern 140.

The second portion of the contact pattern BC may extend in the third direction (Z direction) from the first portion toward the bit line BL and contact the upper surface of the second portion CP2 of the channel pattern CP. Accordingly, the contact pattern BC may be electrically connected to the second portion CP2 of the channel pattern CP and may be electrically connected to the first portion CP1 of the channel pattern CP through the second portion CP2 of the channel pattern CP.

One side of the second portion of the contact pattern BC in the first direction (Y direction) may contact the first insulating pattern 120, and the other side in the first direction (Y direction) may contact the gate insulating pattern Gox. A lower surface of the second portion of the contact pattern BC may be located at a lower level than the upper surfaces of the word lines WL1 and WL2, but is not limited thereto. For example, the lower surface of the second portion of the contact pattern BC may be located at a level substantially the same as or higher than the upper surfaces of the word lines WL1 and WL2. The contact pattern BC may include doped polysilicon, metal, conductive metal nitride, conductive metal oxide, or a combination thereof. For example, the contact pattern BC may include Al, Cu, Ti, Ta, Ru, W, Mo, Pt, Ni, Co, TiN, TaN, WN, NbN, TiAl, TiAlN, TiSi, TiSiN, TaSi, TaSiN, RuTiN, NiSi, CoSi, IrOₓ, RuOₓ, or a combination thereof, but is not limited thereto.

In some embodiments, a landing pad may be disposed on the contact pattern BC. The landing pad may be arranged to overlap at least a part of the contact pattern BC in the third direction (Z direction). The landing pads may be arranged to be spaced apart from each other in the first direction (Y direction) and the second direction (X direction). The landing pads may be arranged in matrix form, but this is only an example and is not limited thereto. The landing pads may be arranged in various shapes, such as a honeycomb shape. In addition, the landing pad may have a circular, oval, rectangular, square, rhombus, or hexagonal shape on a plane, but the planar shape of the landing pad is not limited thereto.

The landing pad may include doped polysilicon, metal, conductive metal nitride, conductive metal oxide, or combinations thereof. For example, the landing pad may include Al, Cu, Ti, Ta, Ru, W, Mo, Pt, Ni, Co, TiN, TaN, WN, NbN, TiAl, TiAlN, TiSi, TiSiN, TaSi, TaSiN, RuTiN, NiSi, CoSi, IrOₓ, RuOₓ, or a combination thereof, but is not limited thereto.

The interlayer insulating layer 150 may fill space between the contact patterns BC disposed to be spaced apart in the first direction (Y direction) on the first insulating pattern 120 and the third insulating pattern 140. For example, a lower surface of the interlayer insulating layer 150 may be located at substantially the same level as the lower surface of the first portion of the contact pattern BC, but is not limited thereto.

The data storage patterns may be respectively disposed on the landing pads LP. The data storage patterns DSP may be electrically connected to the channel patterns CP respectively through the landing pads LP. As shown in FIG. 1, the data storage patterns DSP may be arranged in matrix form in the first direction (Y direction) and the second direction (X direction). In an embodiment, the data storage pattern DSP may be a capacitor and may include lower and upper electrodes and a capacitor dielectric film interposed therebetween. When the data storage pattern DSP is a capacitor, the lower electrode may contact the landing pad LP, and the lower electrode may have various shapes such as circular, oval, rectangular, square, rhombus, or hexagonal shape on the plane.

In contrast, the data storage pattern DSP may be a variable resistance pattern that is switchable between two resistance states by electrical pulses applied to a memory element. For example, the data storage pattern DSP may include a phase-change material whose crystal state changes depending on the amount of current, a perovskite compound, transition metal oxide, a magnetic material, a ferromagnetic material, or an antiferromagnetic material.

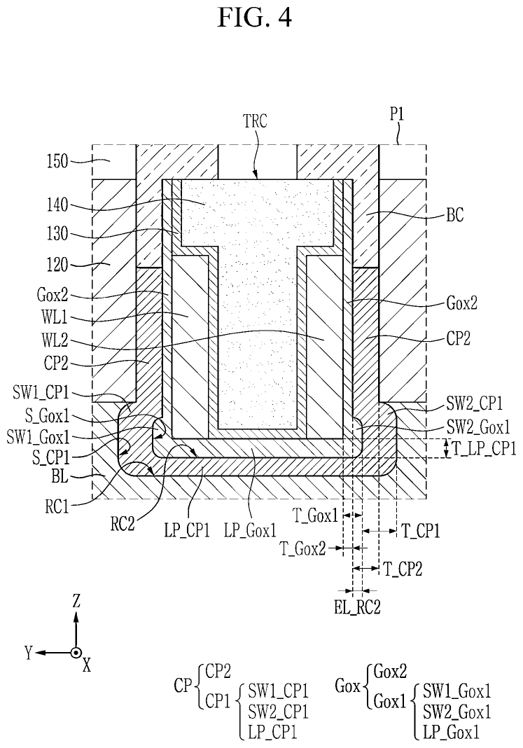

Hereinafter, some embodiments of a semiconductor device are described with reference to FIG. 4. In the following embodiments, the same components as the above-described embodiments are referred to by the same reference numerals, redundant descriptions thereof are omitted or simplified, and the differences are mainly explained.

FIG. 4 is a diagram for explaining a semiconductor device according to some embodiments and is a cross-sectional view corresponding to FIG. 3. FIG. 3 shows that the first portion CP1 of the channel pattern CP fills the extension portion EL_RC1 of the first recess RC1, and the thickness T_CP1 of the first sidewall portion SW1_CP1 or the second sidewall portion SW2_CP1 of the first portion CP1 of the channel pattern CP in the first direction (Y direction) is greater than the thickness T_CP2 of the second portion CP2 of the channel pattern CP in the first direction (Y direction). On the other hand, it is shown that the gate insulating pattern Gox conformally covers the channel pattern CP.

Referring to FIG. 4, the first portion CP1 of the channel pattern CP fills the extension portion EL_RC1 of the first recess RC1, but the thickness T_CP1 of the first sidewall portion SW1_CP1 or the second sidewall portion SW2_CP1 of the first portion CP1 of the channel pattern CP in the first direction (Y direction) may not be greater than the thickness T_CP2 of the second portion CP2 of the channel pattern CP in the first direction (Y direction) and may be substantially the same as the thickness T_CP2.

In other words, the channel pattern CP may have an overall conformal shape. That is, the channel pattern CP may cover on the bottom surface of the first recess RC1 of the bit line BL, the sidewall of the first recess RC1 of the bit line BL, and the sidewall of the first insulating pattern 120 to a certain thickness. Accordingly, an inner surface of the first portion CP1 of the channel pattern CP may have a second recess RC2 that opens in the third direction (Z direction). A width of the second recess RC2 in the first direction (Y direction) may be greater than a width of an opening of the second recess RC2 in the first direction (Y direction). Here, the width of the opening of the second recess RC2 in the first direction (Y direction) may be a width of the second recess RC2 in the first direction (Y direction) from the uppermost end of the second recess RC2 in the third direction (Z direction). In addition, the width of the second recess RC2 in the first direction (Y direction) may be greater than the minimum distance between a pair of second portions CP2 of the channel pattern CP in the first direction (Y direction).

In addition, the width of the second recess RC2 in the channel pattern CP in the first direction (Y direction) may have the maximum value at any point within the channel pattern CP, and the width of the second recess RC2 in the channel pattern CP in the first direction (Y direction) may have the maximum value at the uppermost end or lowermost end of the second recess RC2 in the third direction (Z direction). For example, the width W_RC of the second recess RC2 in the channel pattern CP in the first direction (Y direction) may have a shape gradually increasing toward the inside of the first portion CP1 of the channel pattern CP, that is, downward in the third direction (Z direction), reaching the maximum value, and then gradually decreasing.

Accordingly, the second recess RC2 of the channel pattern CP may have an extension portion EL_RC2 protruding toward the first sidewall portion SW1_CP1 and the second sidewall portion SW2_CP1 of the first portion CP1 of the channel pattern CP in the first direction (Y direction). Here, the extension portion EL_RC2 of the second recess RC2 refers to a portion in which the width W_RC of the second recess RC2 in the first direction (Y direction) is greater than the minimum distance between the pair of second portions CP2 of the channel pattern CP in the first direction (Y direction).

At this time, the gate insulating pattern Gox includes a first portion Gox1 inserted into the bit line BL and a second portion Gox2 located above the bit line BL. In other words, the first portion Gox1 of the gate insulating pattern Gox is located in the first recess RC1, and the second portion Gox2 is located above the bit line BL. In addition, the first portion Gox1 of the gate insulating pattern Gox may include a first sidewall portion SW1_Gox1 and a second sidewall portion SW2_Gox1 which are respectively located within the second recess RC2 of the channel pattern CP and are disposed adjacent to sidewalls of the second recess RC2 of the channel pattern CP facing each other in the first direction (Y direction), and a lower end portion LP_Gox1 disposed on a bottom surface of the second recess RC2 and connecting between the first sidewall portion SW1_Gox1 and the second sidewall portion SW2_Gox1.

The second portion Gox2 of the gate insulating pattern Gox may be located adjacent to a sidewall of the second portion CP2 of the channel pattern CP. In addition, the second portion Gox2 of the gate insulating pattern Gox may be located above the bit line BL, and may be located on each of the first sidewall portion SW1_Gox1 and second sidewall portion SW2_Gox1 of the first portion Gox1 of the gate insulating pattern Gox. Accordingly, the gate insulating pattern Gox may have an overall “U” shape on a cross-section cut in the first direction (Y direction) and the third direction (Z direction).

The first portion Gox1 of the gate insulating pattern Gox may fill the extended portion EL_RC2 of the second recess RC2. Accordingly, a thickness T_Gox1 of the first sidewall portion SW1_Gox1 or the second sidewall portion SW2_Gox1 of the first portion Gox1 of the gate insulating pattern Gox in the first direction (Y direction) may be greater than a thickness T_Gox2 of the second portion Gox2 of the gate insulating pattern Gox in the first direction (Y direction). Here, the thickness T_Gox1 of the first sidewall portion SW1_Gox1 or the second sidewall portion SW2_Gox1 of the first portion Gox1 of the gate insulating pattern Gox in the first direction (Y direction) may be the maximum thickness of the first sidewall portion SW1_Gox1 or the second sidewall portion SW2_Gox1 of the first portion Gox1 of the gate insulating pattern Gox in the first direction (Y direction), and the thickness T_Gox2 of the second portion Gox2 of the gate insulating pattern Gox in the first direction (Y direction) may be the maximum thickness of the second portion Gox2 of the gate insulating pattern Gox in the first direction (Y direction).

In addition, the thickness T_Gox1 of the first sidewall portion SW1_Gox1 or the second sidewall portion SW2_Gox1 of the first portion Gox1 of the gate insulating pattern Gox in the first direction (Y direction) may be greater than a thickness T_LP_Gox1 of the lower end portion LP_Gox1 of the first portion Gox1 of the gate insulating pattern Gox in the third direction (Z direction). Here, the thickness T_LP_Gox1 of the lower end portion LP_Gox1 of the first portion Gox1 of the gate insulating pattern Gox in the third direction (Z direction) may be the maximum thickness of the lower end portion LP_Gox1 of the first portion Gox1 of the gate insulating pattern Gox in the third direction (Z direction).

In addition, the thickness T_Gox1 of the first sidewall portion SW1_Gox1 or the second sidewall portion SW2_Gox1 of the first portion Gox1 of the gate insulating pattern Gox in the first direction (Y direction) may have the maximum value at any point inside the second recess RC2, and the thickness T_Gox1 of the first sidewall portion SW1_Gox1 or the second sidewall portion SW2_Gox1 of the first portion Gox1 of the gate insulating pattern Gox in the first direction (Y direction) may have the minimum value in the uppermost end or the lowermost end of the second recess RC2 in the third direction (Z direction). For example, the thickness T_Gox1 of the first sidewall portion SW1_Gox1 or the second sidewall portion SW2_Gox1 of the first portion Gox1 of the gate insulating pattern Gox in the first direction (Y direction) may have a shape gradually increasing toward the inside of the second recess RC2, that is, downward in the third direction (Z direction), reaching the maximum value, and then gradually decreasing.

Accordingly, the first portion Gox1 of the gate insulating pattern Gox may have a surface S_Gox1 in contact with the channel pattern CP in the first direction (Y direction) in a convex shape toward the channel pattern CP, that is, the first sidewall portion SW1_Gox1 or the second sidewall portion SW2_Gox1 of the first portion_Gox1 of the gate insulating pattern Gox may have a shape that protrudes toward the channel pattern CP. For example, the gate insulating pattern Gox may have an overall conformal shape. That is, the gate insulating pattern Gox may cover an inner surface of the second recess RC2 and a sidewall of the second portion CP2 of the channel pattern CP to a certain thickness, and the thickness T_Gox2 of the second portion Gox2 of the gate insulating pattern Gox in the first direction (Y direction) and the thickness T_LP_Gox1 of the lower end portion LP_Gox1 of the first portion Gox1 of the gate insulating pattern Gox in the third direction (Z direction) may be similar to each other.

However, as the first portion Gox1 of the gate insulating pattern Gox fills the extension portion EL_RC2 of the second recess RC2, the thickness T_Gox1 of the first sidewall portion SW1_Gox1 or the second sidewall portion SW2_Gox1 of the first portion Gox1 of the gate insulating pattern Gox in the first direction (Y direction) may be greater than each of the thickness T_Gox2 of the second portion Gox2 of the gate insulating pattern Gox in the first direction (Y direction) and the thickness T_LP_Gox1 of the lower end portion LP_Gox1 of the first portion Gox1 of the gate insulating pattern Gox in the third direction (Z direction).

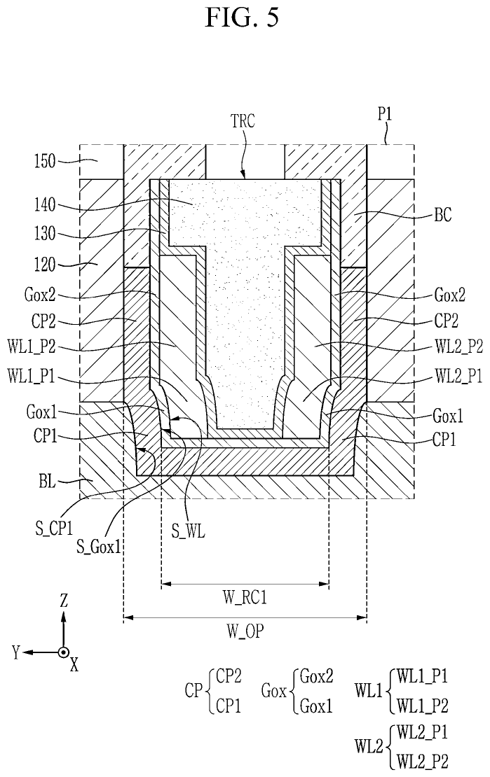

Hereinafter, some embodiments of a semiconductor device are described with reference to FIG. 5. In the following embodiments, the same components as the above-described embodiments are referred to by the same reference numerals, redundant descriptions thereof are omitted or simplified, and the differences are mainly explained.

FIG. 5 is a diagram for explaining a semiconductor device according to some embodiments and is a cross-sectional view corresponding to FIG. 3. FIG. 3 shows that the extension portion EL_RC1 of the first recess RC1 of the bit line BL has the surface S_CP1 in contact with the bit line BL in the first direction (Y direction) in a convex shape toward the bit line BL, that is, the extension portion EL_RC1 of the first recess RC1 has a shape that protrudes toward the bit line BL.

FIG. 5 shows that the extension portion EL_RC1 of the first recess RC1 of the bit line BL has the surface S_CP1 in contact with the bit line BL in the first direction (Y direction) in a concave shape toward the bit line BL, that is, the bit line BL has a shape that protrudes toward the first recess RC1. Accordingly, the width W_RC of the first recess RC1 in the first direction (Y direction) in the bit line BL may be greater than a distance between the first insulating patterns 120 in the first direction (Y direction), that is, a width of the first trench TRC1 in the first direction (Y direction). Here, the width W_RC of the first recess RC1 in the first direction (Y direction) may be the minimum width among widths of the first recess RC1 in the first direction (Y direction).

In addition, the width W_RC of the first recess RC1 in the first direction (Y direction) may be smaller than the width W_OP of an opening of the first recess RC1 in the first direction (Y direction). In addition, the width W_RC of the first recess RC1 in the first direction (Y direction) may be smaller than a distance between the first insulating patterns 120 in the first direction (Y direction). In addition, the width W_RC of the first recess RC1 in the first direction (Y direction) may be smaller than the width of the first trench TRC1 (in FIG. 10) in the first direction (Y direction), which will be described below.

In addition, the width W_RC of the first recess RC1 in the first direction (Y direction) in the bit line BL may have the minimum value at any point inside the bit line BL, and the width W_RC of the first recess RC1 in the first direction (Y direction) in the bit line BL may have the maximum value in the uppermost end of the first recess RC1 in the third direction (Z direction). As described above, a contact area between the bit line BL and the channel pattern CP increases, and thus, a contact resistance of the semiconductor device may be reduced, and the on current Iₒₙ may be improved.

At this time, the channel pattern CP may have a conformal shape. That is, the channel pattern CP may have an overall conformal shape. That is, the channel pattern CP may cover a bottom surface of the first recess RC1 of the bit line BL, a sidewall of the first recess RC1 of the bit line BL, and a sidewall of the first insulating pattern 120 to a certain thickness, and the thickness T_CP1 of the first sidewall portion SW1_CP1 or the second sidewall portion SW2_CP1 of the first portion CP1 of the channel pattern CP in the first direction (Y direction) may be similar to each of the thickness T_CP2 of the second portion CP2 of the channel pattern CP in the first direction (Y direction) and the thickness T_LP_CP1 of the lower end portion LP_CP1 of the first portion CP1 of the channel pattern CP in the third direction (Z direction).

The gate insulating pattern Gox includes the first portion Gox1 inserted into the bit line BL and the second portion Gox2 located above the bit line BL. In other words, the first portion Gox1 of the gate insulating pattern Gox is located in the first recess RC1, and the second portion Gox2 is located above the bit line BL. The gate insulating pattern Gox may have a conformal shape. That is, the gate insulating pattern Gox may cover an inner surface of the second recess RC2 and a sidewall of the second portion CP2 of the channel pattern CP to a certain thickness, and the thickness T_Gox1 of the first sidewall portion SW1_Gox1 or the second sidewall portion SW2_Gox1 of the first portion Gox1 of the gate insulating pattern Gox in the first direction (Y direction) may be similar to each of the thickness T_Gox2 of the second portion Gox2 of the gate insulating pattern Gox in the first direction (Y direction) and the thickness T_LP_Gox1 of the lower end portion LP_Gox1 of the first portion Gox1 of the gate insulating pattern Gox in the third direction (Z direction).

The first portion Gox1 of the gate insulating pattern Gox may have the surface S_Gox1 in contact with the channel pattern CP in the first direction (Y direction) in a concave shape toward the first portion CP1 of the channel pattern CP, that is, the first portion CP1 of the channel pattern CP may have a shape that protrudes toward the first sidewall portion SW1_Gox1 or the second sidewall portion SW2_Gox1 of the first portion_Gox1 of the gate insulating pattern Gox.

In addition, the word lines WL1 and WL2 each include first portions WL1_P1 and WL2_P1 inserted into the bit line BL and second portions WL1_P2 and WL2_P2 located above the bit line BL. In other words, the first portions WL1_P1 and WL2_P1 of the word lines WL1 and WL2 are located in the first recess RC1, and the second portions WL1_P2 and WL2_P2 are located above the bit line BL.

The respective first portions WL1_P1 and WL2_P1 of the word lines WL1 and WL2 may have a surface S_WL in contact with the gate insulating pattern Gox in the first direction (Y direction) in a concave shape toward the first portion Gox1 of the gate insulating pattern Gox, that is, the first portion Gox1 of the gate insulating pattern Gox may have a shape that protrudes toward the respective first portions WL1_P1 and WL2_P1 of the word lines WL1 and WL2.

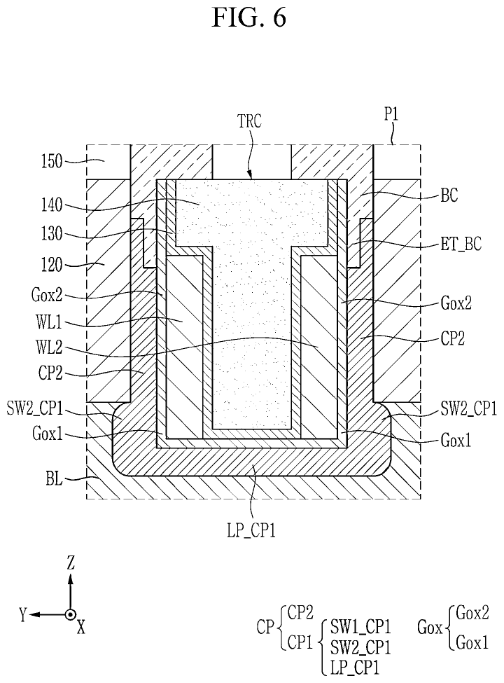

Hereinafter, some embodiments of a semiconductor device are described with reference to FIG. 6. In the following embodiments, the same components as the above-described embodiments are referred to by the same reference numerals, redundant descriptions thereof are omitted or simplified, and the differences are mainly explained.

FIG. 6 is a diagram for explaining a semiconductor device according to some embodiments and is a cross-sectional view corresponding to FIG. 3. FIG. 3 shows that one side of a second portion of the contact pattern BC in the first direction (Y direction) contacts the first insulating pattern 120, and the other side thereof in the first direction (Y direction) is flat and contacts the gate insulating pattern Gox. FIG. 6 shows that the contact pattern BC further includes an extension portion BC_ET extending from the second portion in the third direction (Z direction). The extension portion BC_ET of the contact pattern BC may extend from the second portion in the third direction (Z direction) toward the bit line BL and be located between the channel pattern CP and the gate insulating pattern Gox.

In other words, one side of the extension portion BC_ET of the contact pattern BC in the first direction (Y direction) is adjacent to the gate insulating pattern Gox, and the other side of the extension portion BC_ET in the first direction (Y direction) is adjacent to the channel pattern CP. One side of the extension portion BC_ET of the contact pattern BC in the third direction (Z direction) is adjacent to the second portion of the contact pattern BC, and the other side of the extension portion BC_ET in the third direction (Z direction) is adjacent to the channel pattern CP. Accordingly, a contact area between the channel pattern CP and the contact pattern BC increases, which may not only increase Vₒ but also prevent Vₜₕ from decreasing by first passivating the contact pattern BC before sufficiently passivating the channel pattern CP upon passivation of oxygen O₂ in a subsequent process.

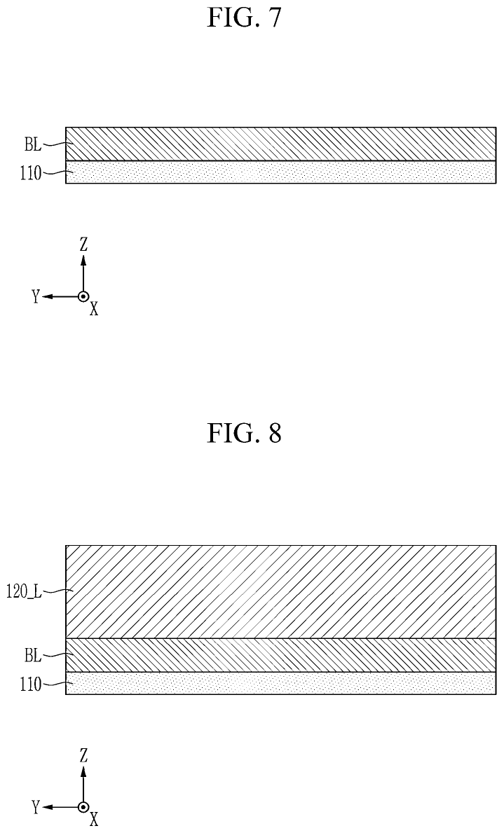

Hereinafter, with reference to FIGS. 7 to 21, a method of manufacturing a semiconductor device according to an embodiment shown in FIGS. 1 to 3 will be described. In FIGS. 7 to 21, for convenience, the peripheral circuit structure PS of FIG. 2 is omitted, and the lower insulating layer 110 formed on the peripheral circuit structure PS is shown. FIGS. 7 to 21 are cross-sectional views for explaining a method of manufacturing a semiconductor memory device according to an embodiment.

Referring to FIG. 7, the bit line BL may be formed on the lower insulating layer 110. The lower insulating layer 110 may include insulating films stacked in multiple layers. For example, the lower insulating layer 110 may include a silicon oxide film, a silicon nitride film, a silicon nitric oxide film, a low-k dielectric film, or a combination thereof. The bit lines BL may extend in the first direction (Y direction) and may be arranged to be spaced apart in the second direction (X direction) that intersects the first direction (Y direction). The bit line BL may be formed by depositing a conductive layer on the lower insulating layer 110 and then patterning the conductive layer.

Although not shown, an insulating material may be filled in space between the bit lines BL. The insulating material may include the same insulating material as the lower insulating layer 110, but is not limited thereto. When the insulating material includes the same insulating material as the lower insulating layer 110, the insulating material may be integrated with the lower insulating layer 110. For example, an upper surface of the lower insulating layer 110 and an upper surface of the bit line BL may be located at substantially the same level.

Referring to FIG. 8, a first insulating pattern material layer 120_L may be formed on the bit line BL and the lower insulating layer 110. For example, the first insulating pattern material layer 120_L may be deposited through a chemical vapor deposition or PVD process, but is not limited thereto. The first insulating pattern material layer 120_L may include at least one of, for example, silicon oxide, silicon nitric oxide, silicon nitride, or a low-k material having a lower dielectric constant than silicon oxide, but is not limited thereto.

Referring to FIG. 9, the first insulating pattern 120 may be formed by patterning the first insulating pattern material layer 120_L. The first insulating patterns 120 may extend in the second direction (X direction) and may form the first insulating patterns 120 defining the first trenches TRC1 spaced apart from each other in the first direction (Y direction). The first trenches TRC1 may intersect the bit line BL, and the first trenches TRC1 may expose an upper surface of the bit line BL.

Referring to FIG. 10, the first recess RC1 is formed by etching the bit line BL. At this time, the first recess RC1 may be formed to have an enlarged structure by over-etching the bit line BL using the first insulating patterns 120 as a mask. In other words, a width of the first recess RC1 in the bit line BL in the first direction (Y direction) may be greater than a distance between the first insulating patterns 120 in the first direction (Y direction), that is, a width of the first trench TRC1 in the first direction (Y direction). Here, the width of the first recess RC1 in first direction (Y direction) may be the maximum width among widths of the first recess RC1 in the first direction (Y direction).

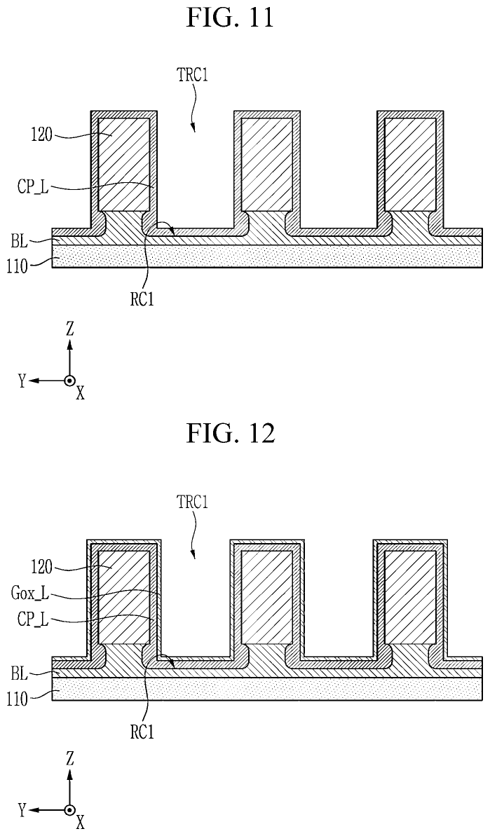

Referring to FIG. 11, a channel pattern material layer CP_L may be formed on upper surfaces of the first insulating patterns 120, sidewalls of the first insulating patterns 120, and inside the first recess RC1. For example, the channel pattern material layer CP_L may be formed through an ALD process. Accordingly, the channel pattern material layer CP_L may be conformally deposited on the upper surfaces of the first insulating patterns 120, the sidewalls of the first insulating patterns 120, and the inside of the first recess RC1. At this time, the channel pattern material layer CP_L may also fill an extension portion of the first recess RC1. For example, the channel pattern material layer CP_L may include an oxide semiconductor material. For example, the channel pattern material layer CP_L may include IGZO, but is not limited thereto.

Although not shown, a spin-on hardmask (SOH) layer may be formed on the channel pattern material layer CP_L. The SOH layer may be formed through a spin coating process. For example, the SOH layer may include carbon, but is not limited thereto. Next, the channel pattern material layer CP_L may be etched by patterning the SOH layer, forming a SOH pattern, and using the SOH pattern as an etch mask. Accordingly, the channel pattern material layer CP_L may be patterned and extend in the first direction (Y direction) on the bit line BL and be spaced apart in the second direction (X direction). The channel pattern material layer CP_L may cover an upper surface of the bit line BL and sidewall and upper surface of the first insulating pattern 120 in the first direction (Y direction). Next, the SOH pattern may be removed. For example, the SOH pattern may be removed through an ashing or strip process.

Referring to FIG. 12, a gate insulating pattern material layer Gox_L conformally covering the channel pattern material layer CP_L may be formed. For example, the gate insulating pattern material layer Gox_L may be deposited through a CVD, PVD, or ALD process, but is not limited thereto. The gate insulating pattern material layer Gox_L may include silicon oxide, silicon nitric oxide, a high-k material having a higher dielectric constant than silicon oxide, or a combination thereof. The high-k material may include metal oxide or metal nitric oxide.

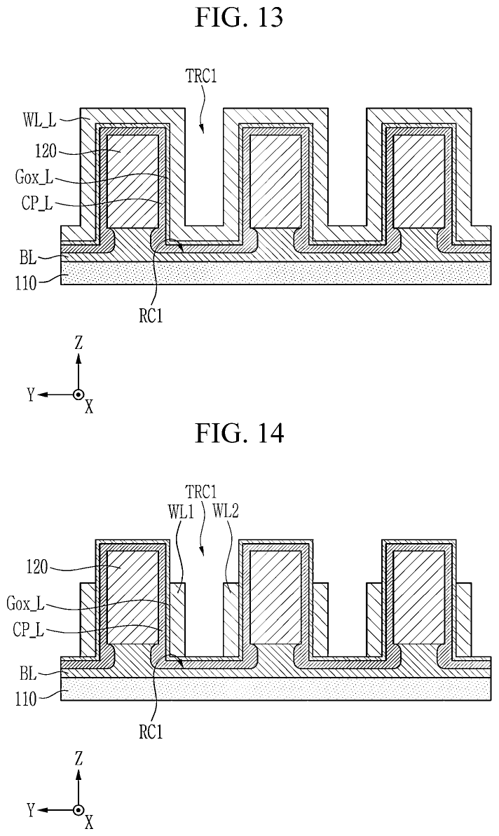

Referring to FIG. 13, a word line material layer WL_L conformally covering the gate insulating pattern material layer Gox_L may be formed. For example, the word line material layer WL_L may be deposited through the CVD, PVD, or ALD process, but is not limited thereto. The word line material layer WL_L may include doped polysilicon, metal, conductive metal nitride, conductive metal silicide, conductive metal oxide, or a combination thereof.

Referring to FIG. 14, a pair of second word lines WL1 and WL2 spaced apart from each other in the first direction (Y direction) in the first trench TRC1 may be formed by performing an anisotropic etching process on the word line material layer WL_L. During the anisotropic etching process on the word line material layer WL_L, upper surfaces of the word lines WL1 and WL2 may be lower than the upper surface of the channel pattern material layer CP_L, the upper surface of the gate insulating pattern material layer Gox_L, and the upper surface of the first insulating pattern 120. In some embodiments, an etching process to recess the upper surfaces of the word lines WL1 and WL2 may be additionally performed.

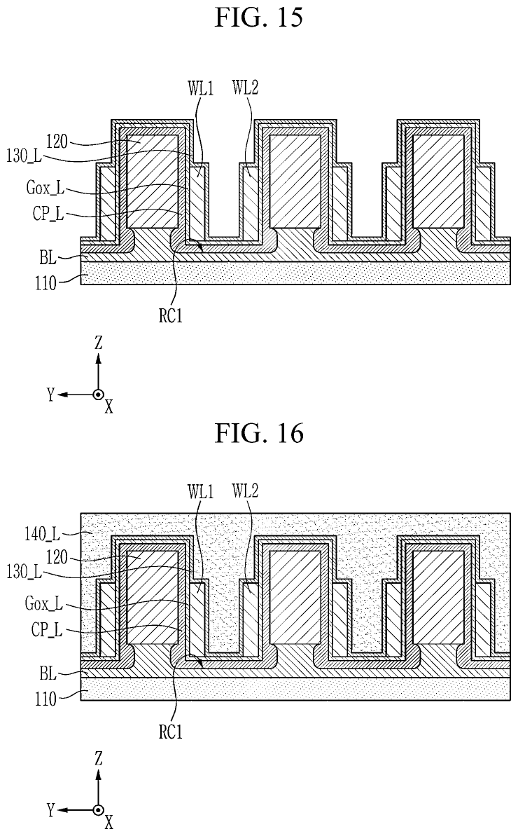

Referring to FIG. 15, a second insulating pattern material layer 130_L conformally covering the gate insulating pattern material layer Gox_L and the word lines WL1 and WL2 may be formed. For example, the second insulating pattern material layer 130_L may be deposited through the CVD, PVD, or ALD process, but is not limited thereto. The second insulating pattern material layer 130_L may include at least one of, for example, silicon oxide, silicon nitric oxide, silicon nitride, or a low-k material having a smaller dielectric constant than silicon oxide, but is not limited thereto.

Referring to FIG. 16, a third insulating pattern material layer 140_L filling the first trench TRC1 remaining after the second insulating pattern material layer 130_L is formed may be formed. The third insulating pattern material layer 140_L may cover an upper surface of the first trench TRC1 and an upper surface of the second insulating pattern material layer 130_L. For example, the third insulating pattern material layer 140_L may be deposited through the CVD, PVD, or ALD process, but is not limited thereto. The third insulating pattern material layer 140_L may include at least one of, for example, silicon oxide, silicon nitric oxide, silicon nitride, or a low-k material having a lower dielectric constant than silicon oxide, but is not limited thereto. The third insulating pattern material layer 140_L may include a material different from that of the second insulating pattern material layer 130_L, but is not limited thereto. When the second insulating pattern material layer 130_L and the third insulating pattern material layer 140_L include the same material, the second insulating pattern material layer 130_L and the third insulating pattern material layer 140_L may be integrally formed.

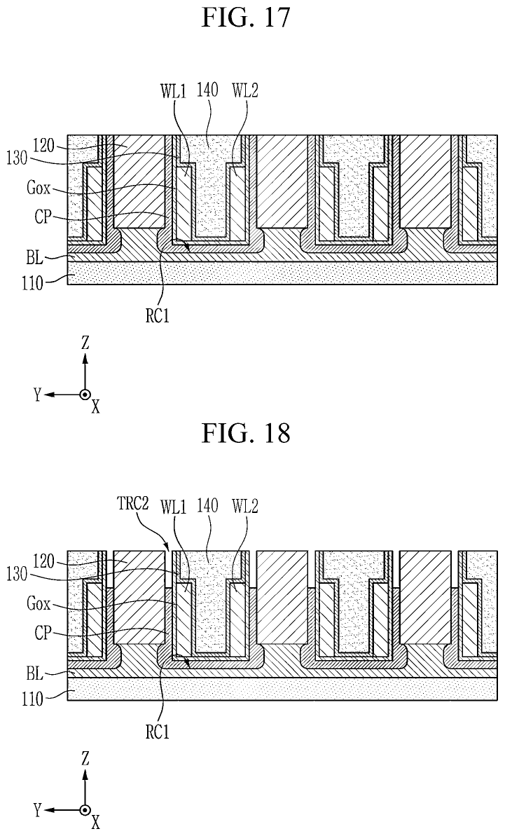

Referring to FIG. 17, the channel pattern CP, the gate insulating pattern Gox, the second insulating pattern 130, and the third insulating pattern 140 may be formed through a planarization process. Through the planarization process, an upper surface of the first insulating pattern 120, an upper surface of the channel pattern CP, an upper surface of the gate insulating pattern Gox, an upper surface of the second insulating pattern 130, and an upper surface of the third insulating pattern 140 may be exposed. That is, a part of the channel pattern material layer CP_P, a part of the gate insulating pattern material layer Gox_L, a part of the second insulating pattern material layer 130_L, and a part of the third insulating pattern material layer 140_L located at a higher level than the upper surface of the first insulating pattern 120 may be removed through the planarization process.

Referring to FIG. 18, the second trench TRC2 may be formed through an etching process to recess a part of the channel pattern CP. Specifically, the second trench TRC2 extending in the third direction (Z direction) may be formed by etching the channel pattern CP from the upper surface to the lower surface. For example, a part of the channel pattern CP may be wet-etched using an etchant that selectively etches the channel pattern CP. However, an etching process to recess the channel pattern CP is not limited thereto and may be changed in various ways.

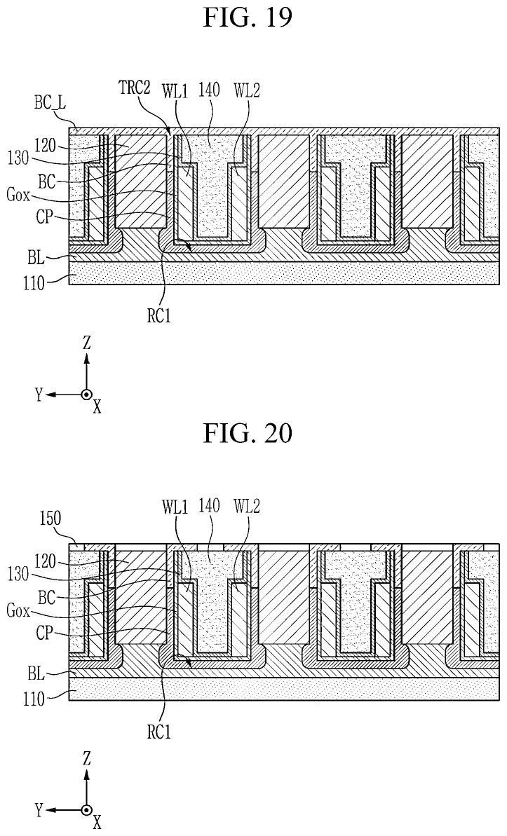

Referring to FIG. 19, a contact pattern material layer BC_L covering the upper surfaces of the first to third insulating patterns 120, 130, and 140 and the upper surface of the gate insulating pattern Gox, and filling the second trench TRC2 may be formed. The contact pattern material layer BC_L may fill the second trench TRC2 and may contact the upper surface of the channel pattern CP2.

Referring to FIG. 20, the planarization process may be performed by patterning the contact pattern material layer BC_L and forming holes exposing the upper surfaces of the first and third insulating patterns 120 and 140, and then burying the interlayer insulating layer 150 in the holes. Accordingly, the contact pattern BC may be formed. However, the order of forming the contact pattern BC and the interlayer insulating layer 150 is not limited thereto. In some embodiments, a landing pad may be further formed on the contact pattern BC.

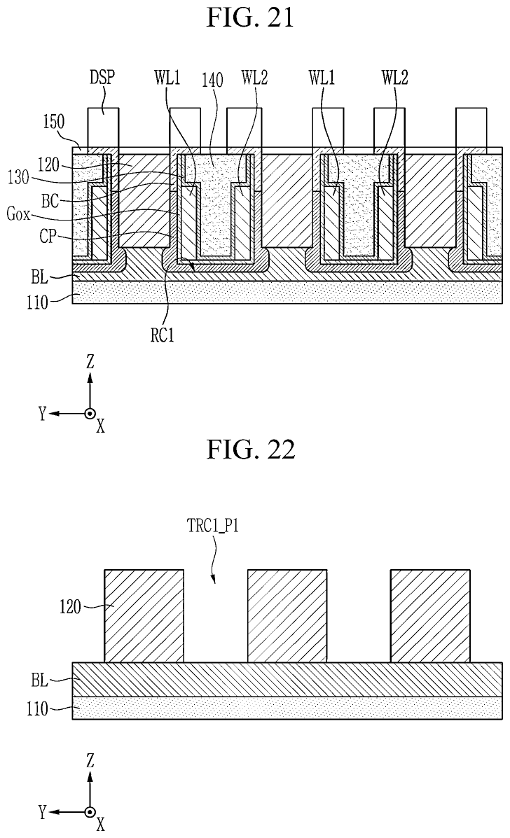

Referring to FIG. 21, the data storage patterns DSP may be respectively formed on the contact patterns BC. In an embodiment, the data storage pattern DSP may be a capacitor including a lower electrode, a capacitor dielectric layer, and an upper electrode. In this case, the lower electrode may contact the contact pattern BC.

Hereinafter, with reference to FIGS. 22 to 24, a method of manufacturing a semiconductor device according to an embodiment shown in FIG. 5 will be described. In FIGS. 22 to 24, for convenience, the peripheral circuit structure PS of FIG. 2 is omitted, and the lower insulating layer 110 formed on the peripheral circuit structure PS is shown. FIGS. 22 to 24 are diagrams for explaining a method of manufacturing a semiconductor memory device according to some embodiments, and are cross-sectional views corresponding to FIGS. 9 and 10.

Referring to FIG. 22, the first insulating pattern 120 is formed by patterning the first insulating pattern material layer 120_L, but unlike FIG. 9, a preliminary first trench TRC1_P1 whose width in the first direction (Y direction) is narrower than a width of the first trench TRC1.

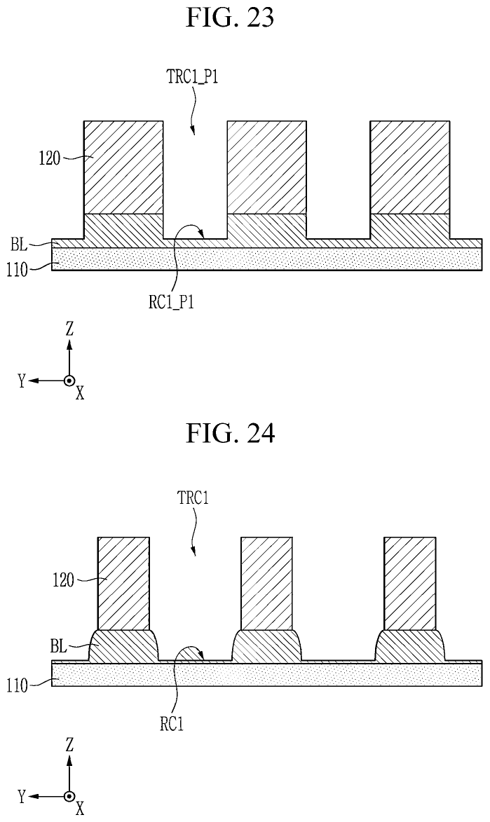

Referring to FIG. 23, a preliminary first recess RC1_P1 is formed by etching the bit line BL using the preliminary first trenches TRC1_P1 as a mask. At this time, unlike FIG. 10, the bit line BL is not over-etched.

Referring to FIG. 24, the first trenches TRC1 are formed by etching sidewalls of the first insulating patterns 120 using a mask. That is, widths of the first trenches TRC1 in the first direction (Y direction) are greater than widths of the preliminary first trenches TRC1_P1 in the first direction (Y direction). At this time, the bit line BL in the preliminary first recess RC1_P1 is also partially etched and the first recess RC1 is formed. Accordingly, the extension portion EL_RC1 of the first recess RC1 of the bit line BL may have the surface S_CP1 in contact with the bit line BL in the first direction (Y direction) in a concave shape toward the bit line BL, that is, the bit line BL may have a shape that protrudes toward the first recess RC1.

In addition, a width of the first recess RC1 in the first direction (Y direction) may be smaller than a distance between the first insulating patterns 120 in the first direction (Y direction), that is, the width of the first trench TRC1 in the first direction (Y direction). Here, the width of the first recess RC1 in the first direction (Y direction) may be the minimum width among widths of the first recess RC1 in the first direction (Y direction).

Although the embodiments of the present disclosure have been described in detail above, the scope of the present disclosure is not limited thereto, and various modifications and improvements made by those of ordinary skill in the field to which the present disclosure pertains also belong to the scope of the present disclosure.

1. A semiconductor device, comprising:
a bit line extending in a first direction across an underlying substrate, said bit line having an opening therein at a first surface thereof and a recess within the opening, said recess having a greater lateral width as measured in the first direction relative to a width of the opening as measured in the first direction;
a channel pattern extending through the opening and at least partially filling the recess, said channel pattern extending in a second direction orthogonal to the first direction;
a first word line extending through the opening and into the recess, and extending lengthwise in the second direction; and
a gate insulating pattern extending between the channel pattern and the first word line.

2. The device of claim 1, wherein the recess includes opposing sidewalls that are concave shaped when viewed from a cross-sectional perspective.

3. The device of claim 2, wherein the channel pattern contacts the opposing concave shaped sidewalls of the recess.

4. The device of claim 1, wherein the channel pattern extends along a bottom and opposing sidewalls of the recess; and wherein the gate insulating pattern extends between the first word line and a first portion of the channel pattern on the bottom of the recess.

5. The device of claim 4, further comprising a second word line extending through the opening and into the recess, and extending lengthwise in the second direction; and wherein the gate insulating pattern extends between the second word line and a second portion of the channel pattern on the bottom of the recess.

6. The device of claim 5, wherein a thickness of the channel pattern as measured between the gate insulating pattern and the bottom of the recess is less than a thickness of the channel pattern as measured between the gate insulating pattern and a sidewall of the recess.

7. The device of claim 6, wherein the channel pattern comprises a semiconductor material.

8. The device of claim 4, wherein a thickness of the gate insulating pattern extending between a bottom of the first word line and the first portion of the channel pattern is greater than a thickness of a portion of the gate insulating pattern extending between the first word line and a portion of the channel pattern extending above the opening in the bit line in a direction normal to the first surface.

9. The device of claim 4, wherein a thickness of the gate insulating pattern extending between a bottom of the first word line and the first portion of the channel pattern is greater than a thickness of a portion of the gate insulating pattern extending between the first word line and a portion of the channel pattern extending above the opening in the bit line in a direction normal to the first surface.

10. The device of claim 5, further comprising:
a first contact pattern of a first memory device electrically connected to the channel pattern; and
a second contact pattern of a second memory device electrically connected to the channel pattern; and
wherein a first portion of the gate insulating pattern extends between the first word line and the first contact pattern, and a second portion of the gate insulating pattern extends between the second word line and the second contact pattern.

11. A semiconductor device, comprising:
a substrate;
a bit line located on the substrate and extending in a first direction;
a word line located above the bit line and extending in a second direction different from the first direction;
a channel pattern spaced apart from the word line in the first direction and comprising an oxide semiconductor material; and
a gate insulating pattern extending between the channel pattern and the word line;
wherein the channel pattern comprises a first portion inserted into the bit line and a second portion located above the bit line; and
wherein a thickness of the first portion of the channel pattern in the first direction is greater than a thickness of the second portion of the channel pattern in the first direction.

12. The device of claim 11, wherein the first portion of the channel pattern has a surface in contact with the bit line in the first direction in a convex shape toward the bit line.

13. An integrated circuit memory device, comprising:
a bit line extending lengthwise in a first direction across an underlying substrate, said bit line having a trench therein with first and second opposing sidewalls;
first and second spaced-apart word lines extending lengthwise in parallel in a second direction across the underlying substrate, which is perpendicular to the first direction, said first word line having a first portion extending opposite the first sidewall of the trench and a second portion extending outside the trench and said second word line having a first portion extending opposite the second sidewall of the trench and a second portion extending outside the trench; and
a channel pattern extending between the first portion of the first word line and the first sidewall of the trench, along a bottom of the trench, and between the first portion of the second word line and the second sidewall of the trench.

14. The memory device of claim 13, wherein each of the first and second opposing sidewalls is concave-shaped or convex-shaped when viewed from a cross-sectional perspective.

15. The memory device of claim 13, further comprising a gate insulating pattern extending between first and second portions of the first word line and the channel pattern and between first and second portions of the second word line and the channel pattern.

16. The memory device of claim 15, wherein the gate insulating pattern extends between the first portion of the first word line and a bottom of the trench and between a first portion of the second word line and the bottom of the trench.

17. A semiconductor device comprising:
a substrate;
a bit line located on the substrate and extending in a first direction;
a word line located above the bit line and extending in a second direction different from the first direction;
a channel pattern spaced apart from the word line in the first direction and comprising an oxide semiconductor material; and
a gate insulating pattern located between the channel pattern and the word line,
wherein the bit line has a recess that opens upward,
the channel pattern comprises a first portion located in the recess and a second portion located above the bit line, and
the first portion of the channel pattern has a surface in contact with the bit line in the first direction in a concave shape toward the bit line.

18. The semiconductor device of claim 17, wherein the channel pattern, the gate insulating pattern, or both have a conformal shape.

19. The semiconductor device of claim 17, wherein the gate insulating pattern includes a first portion located in the recess and a second portion located above the bit line; and
wherein the first portion of the gate insulating pattern has a surface in contact with the first portion of the channel pattern in the first direction in a concave shape toward the first portion of the channel pattern.

20. The semiconductor device of claim 19,
wherein the word line includes a first portion located in the recess and a second portion located above the bit line; and
wherein the first portion of the word line has a surface in contact with the first portion of the gate insulating pattern in the first direction in a concave shape toward the first portion of the gate insulating pattern.

21.-24. (canceled)
